(19) United States
(12) Patent Application Publication
(10) Pub. No.: US 2026/0305501 A1
(43) Pub. Date: Oct. 1, 2026

(54) METHOD FOR MANUFACTURING SEMICONDUCTOR DEVICE AND SEMICONDUCTOR DEVICE

(71) Applicant: Resonac Corporation, Minato-ku, Tokyo (JP)

(72) Inventors: Yoshiki MARUYAMA, Tokyo (JP); Tadashi OKUDA, Tokyo (JP); Shizu FUKUZUMI, Tokyo (JP); Yuta FUJITA, Tokyo (JP)

(21) Appl. No.: 19/479,343

(22) PCT Filed: Aug. 10, 2023
(86) PCT No.: PCT/JP2023/029346

§ 371 Date: Oct. 28, 2025

(51) Int. Cl. H10W 90/00; H10P 52/40; H10W 72/00; H10W 74/10; H10W 74/47; H10W 80/00; H10W 90/26

(52) U.S. Cl. CPC H10W 90/792; H10P 52/409; H10W 72/01904; H10W 72/01951; H10W 74/137; H10W 80/312; H10W 80/314; H10W 80/327; H10W 74/476; H10W 90/26

(57) ABSTRACT

In this method for manufacturing a semiconductor device, first, a substrate 10A including a support substrate 11A, and a conductive part 12A and a polyimide film 13A disposed on the support substrate 11A is prepared. Thereafter, a surface side portion 132 of the polyimide film 13A is cut by a fly-cutting method. In this method for manufacturing a semiconductor device, a tensile modulus of an organic insulating material constituting the polyimide film 13A is 3.5 GPa or less. By using the organic insulating material with such a tensile modulus, wear of an apparatus used for the fly-cutting method is suppressed, and a surface roughness of the substrate 10A can be reduced. Such a substrate 10A can be used, for example, for hybrid bonding.

### TECHNICAL FIELD

The present disclosure relates to a method for manufacturing a semiconductor device and a semiconductor device.

### BACKGROUND ART

In recent years, three-dimensional packaging has been studied to improve the degree of integration of LSIs. Non-Patent Literature 1 discloses an example of three-dimensional packaging of semiconductor chips.

### CITATION LIST

### Patent Literature

Patent Literature 1: F. C. Chen et al., “System on Integrated Chips (SoIC TM) for 3D Heterogeneous Integration”, 2019 IEEE 69th Electronic Components and Technology Conference (ECTC), p.594-599 (2019)

### SUMMARY OF INVENTION

### Technical Problem

When manufacturing a semiconductor device by three-dimensional packaging, the use of hybrid bonding technology, which directly bonds devices to each other, is being considered for miniaturization of wiring between devices. However, if a substrate surface of a device is rough, bonding failures may occur during hybrid bonding. Specifically, the greater a surface roughness of the substrate, the lower a bonding strength between devices may be. Therefore, a method for manufacturing a semiconductor device that can reduce the surface roughness of the substrate is desired.

### Solution to Problem

An object of the present disclosure is to provide a method for manufacturing a semiconductor device that can reduce surface roughness.

### Advantageous Effects of Invention

The present inventors conducted research and investigation on a method for manufacturing a semiconductor device that can reduce a surface roughness of a substrate. As a result, the present inventors have obtained the following findings and have come to conceive the present invention.

When cutting by a fly-cutting method, a degree of wear of the apparatus used for the fly-cutting method affects the surface roughness of the substrate after cutting. For example, when cutting is performed by the fly-cutting method in a state where the wear of the apparatus has progressed, the surface roughness of the substrate after cutting tends to increase. Therefore, in order to reduce the surface roughness of the substrate after cutting, it is desired to reduce the wear of the apparatus used for the fly-cutting method. Therefore, the present inventors focused on a tensile modulus of an organic insulating material included in an insulating film of the substrate, and found that in a case where the tensile modulus of the organic insulating material is 3.5 GPa or less, the wear of the apparatus used for the fly-cutting method is suppressed. That is, the present inventors have found that a method for manufacturing a semiconductor device in which the tensile modulus of the organic insulating material included in the insulating film of the substrate is 3.5 GPa or less can reduce the surface roughness of the substrate. Such a relationship among the tensile modulus of the organic insulating material included in the insulating film of the substrate, the wear of the apparatus used for the fly-cutting method, and the surface roughness of the substrate has not been conventionally considered.

[1] The present disclosure relates to, as one aspect, a method for manufacturing a semiconductor device. This method for manufacturing a semiconductor device includes a preparing a first substrate including a first support substrate and a first insulating film disposed on the first support substrate, the first insulating film including an organic insulating material, and a cutting at least a part of the first insulating film by a fly-cutting method, wherein a tensile modulus of the organic insulating material is 3.5 GPa or less.

In this manufacturing method, the tensile modulus of the organic insulating material included in the first insulating film is 3.5 GPa or less. In this case, as described above, the wear of the apparatus used for the fly-cutting method is suppressed. Therefore, according to the method for manufacturing a semiconductor device of [1] above, the surface roughness of the substrate can be reduced.

[2] The method for manufacturing a semiconductor device of [1] above may further include a polishing a surface of the first insulating film. The polishing may be performed after the cutting. As described above, the greater the surface roughness of the substrate, the lower the bonding strength between devices (between substrates) may be. Here, in order to planarize the substrate surface and reduce the surface roughness, a method of polishing the substrate surface is considered in addition to the cutting by the fly-cutting method described above. However, when only polishing of the substrate surface is performed, although the surface roughness can be further reduced, the polishing work may take time. In the method for manufacturing a semiconductor device of [2] above, a part of the polishing can be replaced by the step of cutting. This makes it possible to reduce the surface roughness while shortening the processing time in the polishing. Therefore, according to the method for manufacturing a semiconductor device of [2] above, the surface roughness can be easily reduced.

[3] In the method for manufacturing a semiconductor device described in [2] above, in the polishing, the surface of the cut first insulating film may be polished by a CMP method. According to the method for manufacturing a semiconductor device of [3] above, the polishing can be performed easily. In addition, the surface roughness of the first insulating film can be more reliably reduced.

[4] In the method for manufacturing a semiconductor device according to any one of [1] to [3] above, the first substrate may further include a first conductive part disposed on the first support substrate. In the cutting, at least a part of the first insulating film may be cut by the fly-cutting method without cutting the first conductive part. According to the method for manufacturing a semiconductor device of [4] above, even when the first substrate includes the first conductive part, the surface roughness of the substrate can be reduced for the reason described above.

[5] The method for manufacturing a semiconductor device of [1] above may further include a preparing a second substrate including a second support substrate and a second insulating film disposed on the second support substrate, and a bonding the first insulating film and the second insulating film. In this case, for the reason described above, the first substrate and the second substrate are bonded in a state where the surface roughness of the first substrate is reduced. Therefore, according to the method for manufacturing a semiconductor device of [5] above, the bonding strength between the first substrate and the second substrate can be improved.

[6] In the method for manufacturing a semiconductor device of [5] above, the first substrate may further include a first conductive part disposed on the first support substrate, and the second substrate may further include a second conductive part disposed on the second support substrate. In the bonding, the first conductive part and the second conductive part may be further bonded. In this case, for the reason described above, the first substrate and the second substrate are bonded in a state where the surface roughness of the first substrate is reduced. Therefore, according to the method for manufacturing a semiconductor device of [6] above, even when the first substrate includes the first conductive part and the second substrate includes the second conductive part, the bonding strength between the first substrate and the second substrate can be improved.

[7] In the method for manufacturing a semiconductor device according to any one of [1] to [6] above, the tensile modulus of the organic insulating material may be 3.0 GPa or less. In this case, the wear of the apparatus used for the fly-cutting method is further suppressed. Therefore, according to the method for manufacturing a semiconductor device of [7] above, the surface roughness of the substrate can be further reduced.

[8] In the method for manufacturing a semiconductor device according to any one of [1] to [7] above, the organic insulating material may be polyimide. According to the method for manufacturing a semiconductor device of [8] above, the first insulating film in which the tensile modulus of the organic insulating material is 3.5 GPa or less can be easily realized.

[9] The present disclosure relates to, as another aspect, a semiconductor device. This semiconductor device includes a first substrate including a first support substrate and a first insulating film disposed on the first support substrate, the first insulating film including an organic insulating material, and a second substrate including a second support substrate and a second insulating film disposed on the second support substrate. An electrode is formed with the first insulating film and the second insulating film are bonded. A tensile modulus of the organic insulating material is 3.5 GPa or less.

In the semiconductor device of [9] above, the first substrate may further include a first conductive part disposed on the first support substrate. The second substrate may further include a second conductive part disposed on the second support substrate. In this semiconductor device, an electrode formed by bonding the first conductive part and the second conductive part may be provided.

In the semiconductor device of [9] or above, the tensile modulus of the organic insulating material may be 3.0 GPa or less.

In the semiconductor device according to any one of [9] to above, the organic insulating material may include polyimide.

In the semiconductor device according to any one of [9] to above, the second insulating film may include an organic insulating material. The tensile modulus of the organic insulating material of the second insulating film may be 3.5 GPa or less.

### BRIEF DESCRIPTION OF DRAWINGS

FIG. 1 is a diagram showing an example of a semiconductor device according to a first embodiment of the present disclosure.

FIG. 2 is a cross-sectional view for explaining a method for manufacturing the semiconductor device shown in FIG. 1, showing an example of a step of preparing a first substrate.

FIG. 3 is a cross-sectional view for explaining the method for manufacturing the semiconductor device shown in FIG. 1, showing an example of a step of cutting a first insulating film by a fly-cutting method.

FIG. 4 is a cross-sectional view for explaining the method for manufacturing the semiconductor device shown in FIG. 1, showing an example of a step of polishing a surface of the cut first insulating film.

FIG. 5 is a cross-sectional view for explaining the method for manufacturing the semiconductor device shown in FIG. 1, showing an example of a step of bonding the first insulating film and a second insulating film.

FIG. 6 is a diagram showing an example of a semiconductor device according to a second embodiment of the present disclosure.

FIG. 7 is a cross-sectional view for explaining a method for manufacturing the semiconductor device shown in FIG. 6, showing an example of a step of preparing a first substrate.

FIG. 8 is a cross-sectional view for explaining the method for manufacturing the semiconductor device shown in FIG. 6, showing an example of a step of cutting a second portion of a first insulating film by a fly-cutting method.

FIG. 9 is a cross-sectional view for explaining the method for manufacturing the semiconductor device shown in FIG. 6, showing an example of a step of polishing a surface of the cut first insulating film.

FIG. 10 is a cross-sectional view for explaining the method for manufacturing the semiconductor device shown in FIG. 6, showing an example of a step of bonding a first conductive part and a second conductive part.

### DESCRIPTION OF EMBODIMENTS

Hereinafter, some embodiments of the present disclosure will be described in detail with reference to the drawings as necessary. In the following description, the same or corresponding parts are denoted by the same reference numerals, and redundant descriptions are omitted. Further, positional relationships such as up, down, left, and right are based on the positional relationships shown in the drawings, unless otherwise specified. When terms such as “left,” “right,” “front,” “back,” “top,” “bottom,” “upper,” and “lower” are used in this specification and the claims, these are for the purpose of explanation and do not necessarily mean that they are permanently in this relative position. Furthermore, the dimensional ratios in the drawings are not limited to the illustrated ratios. In this specification, the term “step” is included in this term not only as an independent step but also if the intended action of the step is achieved even when it cannot be clearly distinguished from other steps.

### First Embodiment

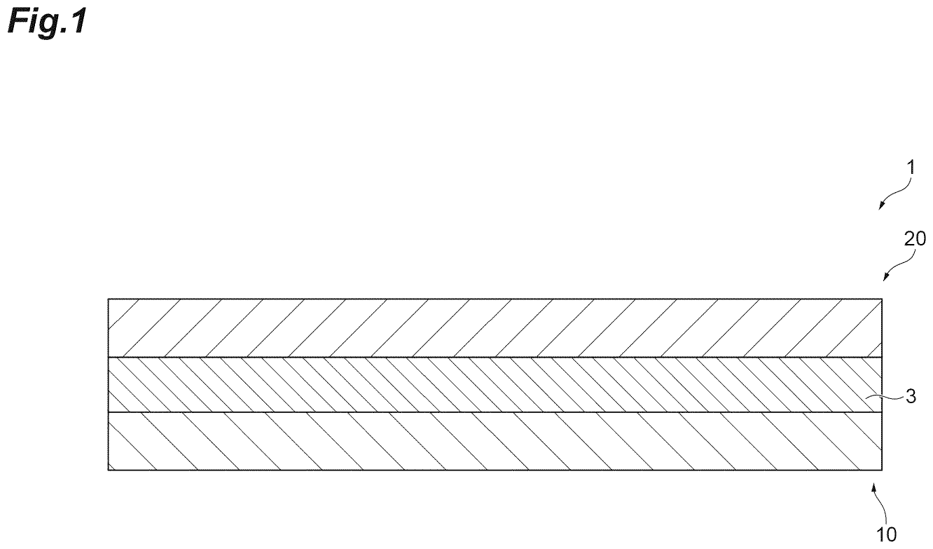

With reference to FIGS. 1 to 6, a semiconductor device and a method for manufacturing the semiconductor device according to a first embodiment of the present disclosure will be described.

### (Configuration of Semiconductor Device)

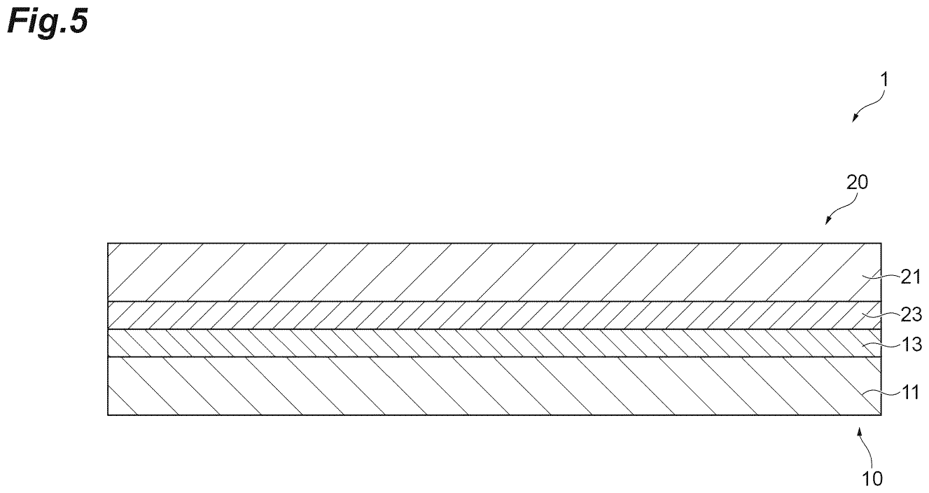

First, with reference to FIG. 1, the configuration of the semiconductor device according to the first embodiment will be described. FIG. 1 shows an example of the semiconductor device according to the first embodiment. As shown in FIG. 1, the semiconductor device 1 is, for example, an example of a semiconductor package, and includes an insulating film 3, a first substrate 10, and a second substrate 20. The insulating film 3 is formed by bonding a first insulating film 13 of a first substrate 10 and a second insulating film 23 of a second substrate 20, which will be described later (see FIG. 5). Here, the tensile modulus of the organic insulating material included in the first insulating film 13, which becomes the insulating film 3, is 3.5 GPa or less, and may be 3.0 GPa or less, and may be 2.8 GPa or less. Furthermore, in a configuration in which the second insulating film 23 also includes an organic insulating material, the tensile modulus of the organic insulating material may be 3.5 GPa or less, may be 3.0 GPa or less, and may be 2.8 GPa or less. The organic insulating material includes, for example, polyimide, a polyimide precursor, polyamide-imide, benzocyclobutene (BCB), polybenzoxazole (PBO), or a PBO precursor.

In the semiconductor device 1, the first substrate 10 and the second substrate 20 are bonded. The first substrate 10 may include a semiconductor element. The semiconductor element included in the first substrate 10 may be disposed on the surface opposite to the second substrate 20 in a state where the first substrate 10 and the second substrate 20 are bonded. The second substrate 20 may also include a semiconductor element. The semiconductor element included in the second substrate 20 may be disposed on the surface opposite to the first substrate 10 in a state where the first substrate 10 and the second substrate 20 are bonded. The semiconductor elements included in the first substrate 10 and the second substrate 20 are, for example, semiconductor chips such as LSI (Large Scale Integrated Circuit) chips, CMOS (Complementary Metal Oxide Semiconductor) sensors, and memories. The semiconductor elements included in the first substrate 10 and the second substrate 20 may be other types of semiconductor chips.

### (Method for Manufacturing Semiconductor Device)

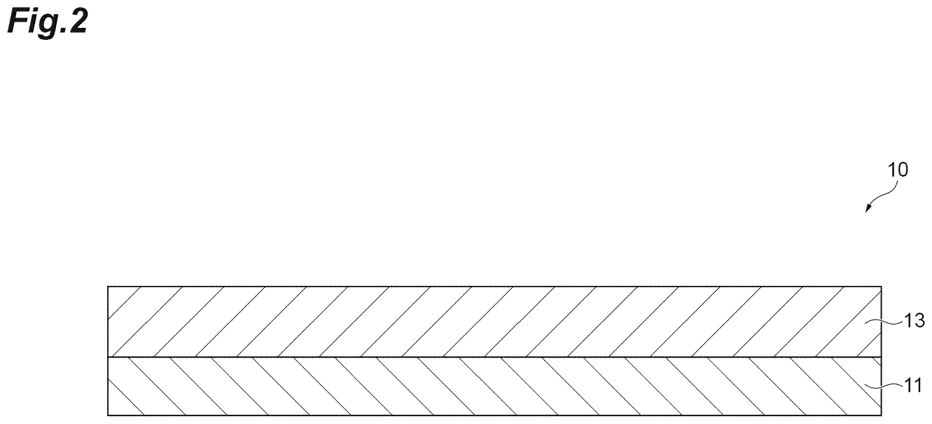

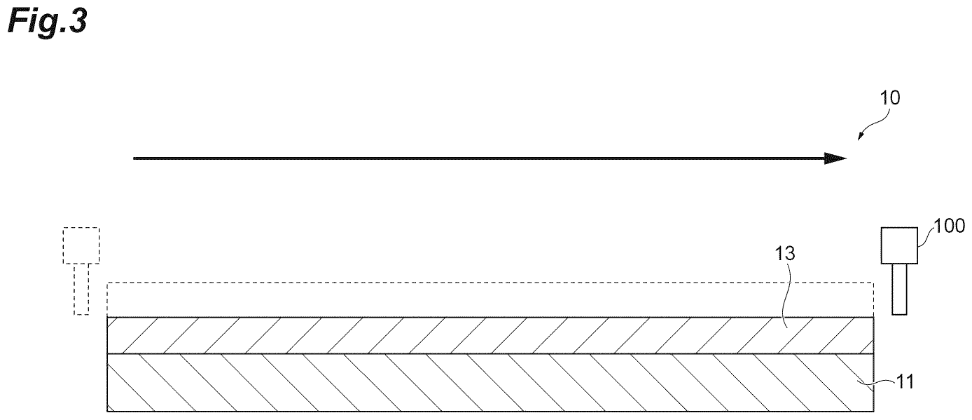

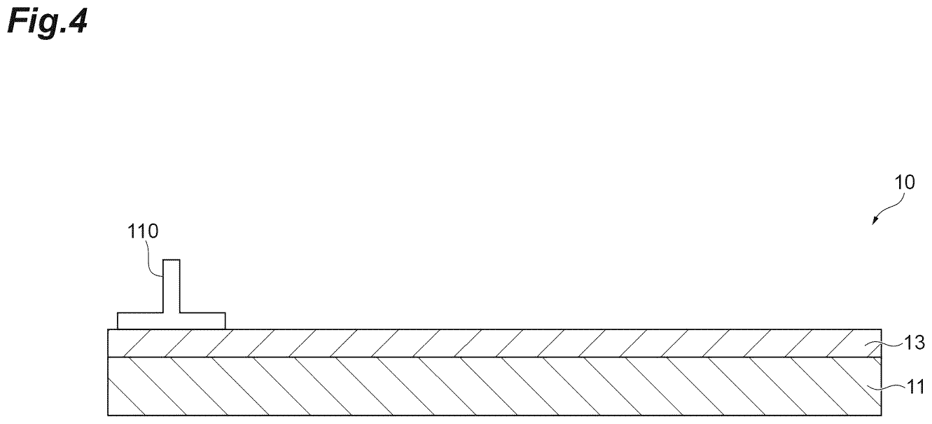

Next, with reference to FIGS. 2 to 5, a method for manufacturing the semiconductor device 1 will be described. FIG. 2 is a cross-sectional view for explaining the method for manufacturing the semiconductor device shown in FIG. 1, showing an example of a step of preparing a substrate. FIG. 3 is a cross-sectional view for explaining the method for manufacturing the semiconductor device shown in FIG. 1, showing an example of a step of cutting the first insulating film by a fly-cutting method. FIG. 4 is a cross-sectional view for explaining the method for manufacturing the semiconductor device shown in FIG. 1, showing an example of a step of polishing the surface of the cut first insulating film. FIG. 5 is a cross-sectional view for explaining the method for manufacturing the semiconductor device shown in FIG. 1, showing an example of a step of bonding the first insulating film and the second insulating film.

The semiconductor device 1 can be manufactured, for example, through the following steps (a) to (g). That is, the method for manufacturing the semiconductor device 1 includes the following steps (a) to (g).

a) A step of preparing a first substrate having a first support substrate and a first insulating film disposed on the first support substrate, the first insulating film including an organic insulating material.

b) A step of cutting at least a part of the first insulating film by a fly-cutting method.

c) A step of polishing a surface of the first insulating film, which is performed after step (b).

d) A step of preparing a second substrate including a second support substrate and a second insulating film disposed on the second support substrate, the second insulating film including an organic insulating material.

e) A step of cutting at least a part of the second insulating film by a fly-cutting method.

f) A step of polishing a surface of the second insulating film, which is performed after step (e).

g) A step of bonding the first substrate and the second substrate, which is performed after steps (c) and (f).

Further, the step (g) of bonding the first substrate and the second substrate includes the following step.

g1) A step of bonding the first insulating film and the second insulating film.

[Step (a)]

Step (a) is a step of preparing the first substrate 10. To prepare the first substrate 10, first, a first support substrate 11 including a first insulating film 13 is prepared. For example, the first support substrate 11 is a silicon wafer. The first support substrate 11 is, for example, a silicon wafer with a thickness of 0.2 mm or more and 2.0 mm or less. A diameter of the first support substrate 11 is, for example, 200 mm, 300 mm, or 450 mm. Alternatively, the first support substrate 11 may be a substrate including a glass plate, a SUS plate, or a glass cloth plate, or may be a resin substrate for sealing a semiconductor element. The first support substrate 11 may be a panel-shaped substrate. In this case, the first support substrate 11 is, for example, a rectangular panel with one side of 300 mm or more and 700 mm or less. The first support substrate 11 may have other configurations.

In the first substrate 10 prepared in step (a), the first insulating film 13 is disposed on the first support substrate 11. The first insulating film 13 is composed of an organic insulating material. The first insulating film 13 may have a configuration that partially includes an organic insulating material. The tensile modulus of the organic insulating material is 3.5 GPa or less, and may be 3.0 GPa or less, and may be 2.8 GPa or less. Such a first insulating film 13 is provided, for example, by applying a liquid organic insulating material onto the surface of the first support substrate 11 by spin coating.

The organic insulating material includes, for example, polyimide, a polyimide precursor, polyamide-imide, benzocyclobutene (BCB), polybenzoxazole (PBO), or a PBO precursor.

A thickness of the first insulating film 13 formed on the first support substrate 11 is, for example, 10 μm or less, preferably 5 μm or less, and more preferably 3 μm or less. Further, the thickness of the first insulating film 13 may be 1 μm or more. Note that the first insulating film 13 may be formed from an inorganic material.

After providing the first insulating film 13, the first insulating film 13 may be heat-cured. In this case, the heating temperature may be, for example, 100° C. or more and 400° C. or less, and the heating time may be set to, for example, 30 minutes or more and 3 hours or less.

Through the above step (a), as shown in FIG. 2, the first substrate 10 including the first support substrate 11 and the first insulating film 13 disposed on the first support substrate 11 is prepared.

[Step (b)]

Step (b) is a step of cutting the first insulating film 13. In step (b), the first insulating film 13 is cut by a fly-cutting method. In one example, at least a part (a surface side portion) of the first insulating film 13 is cut by the fly-cutting method.

In step (b) in the present embodiment, as shown in FIG. 3, the first insulating film 13 is cut by the fly-cutting method so that the surface of the first support substrate 11 is not exposed. That is, in step (b) in the present embodiment, the thickness of the first insulating film 13 is reduced by the fly-cutting method. A thickness of the first insulating film 13 to be cut by the fly-cutting method is, for example, 2 μm or more and 20 μm or less in the stage before cutting. Therefore, at the time when step (b) in the present embodiment is completed, the thickness of the first insulating film 13 is, for example, 1 μm or more and 10 μm or less.

In the fly-cutting method, for example, a grinding apparatus 100 using a diamond cutting tool is used. In this case, as shown in FIG. 3, the first insulating film 13 is cut by moving the grinding apparatus 100 in a predetermined direction on the first substrate 10. As a specific example of the grinding apparatus 100, an automatic surface planer compatible with 300 mm wafers (manufactured by DISCO Corporation, product name “DAS8930”) can be used. Note that the cutting of the first insulating film 13 by the fly-cutting method can also be referred to as a planarization process. Further, in step (b), etching or the like may be combined in addition to the fly-cutting method.

At the time when step (b) in the present embodiment is completed, the surface roughness of the first insulating film 13 cut by the fly-cutting method is, for example, 10 nm or more and 600 nm or less, and may be 200 nm or more and 600 nm or less. The surface roughness in the present embodiment is the arithmetic mean roughness (Ra) defined in JIS B 0601 2001. The surface roughness of the first insulating film 13 after cutting is measured, for example, by scanning a range of 100 μm×100 μm including the first insulating film 13 using a laser microscope (“LEXT OLS3000” manufactured by Olympus Corporation). In the present embodiment, since the first insulating film 13 is configured to include an organic insulating material with the tensile modulus of 3.5 GPa, preferably 3.0 GPa, the surface roughness of the portion cut by the fly-cutting method is suppressed.

[Step (c)]

In step (c) in the present embodiment, as shown in FIG. 4, the remaining portion of the cut first insulating film 13 is polished so that the surface of the first support substrate 11 is not exposed. More specifically, the thickness of the first insulating film 13 is further reduced by polishing the surface of the cut first insulating film 13. That is, in step (c) in the present embodiment, the thickness of the first insulating film 13 is reduced by polishing.

For the above-mentioned polishing, a method such as a grinder for processing electronic materials or a CMP (Chemical Mechanical Polishing) method can be used. In step (c) in the present embodiment, the surface of the first insulating film 13 is polished by the CMP method. In the CMP method, for example, a polishing apparatus 110 is used. In this case, as shown in FIG. 4, by rotating the polishing apparatus 110 while pressing it against the surface of the first insulating film 13, the surface of the first insulating film 13 is polished by mechanical friction between the polishing liquid applied to the surface of the polishing apparatus 110 and the first insulating film 13. Note that the polishing of the surface of the first insulating film 13 by the CMP method can also be referred to as a planarization process.

At the time when step (c) in the present embodiment is completed, the surface roughness of the first insulating film 13 becomes, for example, 0.1 nm or more and 5 nm or less by the above-mentioned polishing. The surface roughness is the arithmetic mean roughness (Ra) defined in JIS B 0601 2001. The surface roughness of the first insulating film 13 after polishing is measured, for example, by a method similar to that for the surface roughness of the first insulating film 13 after cutting.

[Step (d)]

Step (d) is a step of preparing a second substrate 20 different from the first substrate 10. In step (d), a second substrate 20 including a second support substrate 21 and a second insulating film 23 disposed on the second support substrate 21 is prepared. In the second substrate 20 prepared in step (d), the second insulating film 23 covers the surface of the second support substrate 21. Here, the second insulating film 23 may include an organic insulating material or may include an inorganic insulating material. In a configuration in which the second insulating film 23 includes an organic insulating material, the organic insulating material may be 3.5 GPa or less, may be 3.0 GPa or less, and may be 2.8 GPa or less. Since the method for preparing the second substrate 20 is the same as the method for preparing the first substrate 10, a detailed description is omitted, but the second substrate 20 is prepared through the steps described above. The second substrate 20 does not need to have a completely identical configuration to the first substrate 10, and a thickness or forming material of the second support substrate 21, a thickness or forming material of the second insulating film 23, and the like may be different from those of the first substrate 10. Further, the second substrate 20 may be in the form of a silicon wafer, or may be a singulated device.

[Step (e)]

Step (e) is a step of cutting the second insulating film 23. Since the method for cutting the second insulating film 23 is the same as the method for cutting the first insulating film 13, a detailed description is omitted, but the second insulating film 23 is cut through the step shown in FIG. 3. In step (e), the second insulating film 23 is cut by the fly-cutting method so that the surface of the second support substrate 21 is not exposed.

[Step (f)]

Step (f) is a step of polishing the surface of the second insulating film 23, and is a step performed after step (e). Since the method for polishing the surface of the second insulating film 23 is the same as the method for polishing the surface of the first insulating film 13, a detailed description is omitted, but the surface of the second insulating film 23 is polished through the step shown in FIG. 4. In step (f), the remaining portion of the cut second insulating film 23 is polished so that the surface of the second support substrate 21 is not exposed.

[Step (g)]

Step (g) is a step of bonding the first substrate 10 and the second substrate 20, and is a step performed after steps (c) and (f). In step (g), the first insulating film 13 of the first substrate 10 and the second insulating film 23 of the second substrate 20 are bonded. Here, alignment of at least one of the first substrate 10 and the second substrate 20 is performed so that the first insulating film 13 of the first substrate 10 and the second insulating film 23 of the second substrate 20 oppose each other. Alignment of both the first substrate 10 and the second substrate 20 may be performed. For such alignment, an alignment mark or the like may be provided on at least one of the first substrate 10 and the second substrate 20.

When bonding the first substrate 10 and the second substrate 20, after removing organic matter or metal oxides adhering to the surfaces of the first substrate 10 and the second substrate 20, alignment of the second substrate 20 with respect to the first substrate 10 is performed. Then, when the alignment is completed, the first insulating film 13 and the second insulating film 23 are bonded by hybrid bonding. At this time, the first insulating film 13 and the second insulating film 23 may be uniformly heated and then bonded. By bonding the first insulating film 13 and the second insulating film 23, the insulating film 3 of the semiconductor device 1 is formed as shown in FIG. 1.

A temperature difference between the first substrate 10 and the second substrate 20 during bonding is preferably 10° C. or less, for example. By such heat bonding at a uniform temperature, the first insulating film 13 is mechanically and firmly attached to the second insulating film 23. Further, since it is heat bonding at the uniform temperature, positional deviation or the like at the bonding location is unlikely to occur, and high-precision bonding can be performed. Note that the bonding of the first substrate 10 and the second substrate 20 may be performed by other bonding methods, for example, they may be bonded by room temperature bonding or the like.

Through the above steps, the semiconductor device 1 shown in FIG. 1 is manufactured.

As described above, according to the method for manufacturing the semiconductor device 1 of the present embodiment, in the first substrate 10 prepared in step (a), the tensile modulus of the organic insulating material included in the first insulating film 13 is 3.5 GPa or less. In this case, wear of the grinding apparatus 100 used for the fly-cutting method is suppressed. More specifically, in the configuration in which the tensile modulus of the organic insulating material included in the first insulating film 13 is 3.5 GPa or less, wear of the diamond cutting tool of the grinding apparatus 100 is suppressed. Therefore, according to the method for manufacturing the semiconductor device 1, the surface roughness of the first substrate 10 can be reduced.

In the method for manufacturing the semiconductor device 1, after cutting at least a part of the first insulating film 13 by the fly-cutting method in step (b), the surface of the first insulating film 13 is polished in step (c). In this case, a part of step (c) can be replaced by step (b). This makes it possible to reduce the surface roughness while shortening the processing time in step (c). Therefore, according to the method for manufacturing the semiconductor device 1, it is possible to easily reduce the surface roughness.

In the method for manufacturing the semiconductor device 1, in step (c), the surface of the cut first insulating film 13 is polished by the CMP method. According to the method for manufacturing the semiconductor device 1, step (c) can be performed easily. In addition, the surface roughness of the first insulating film 13 can be more reliably reduced.

The method for manufacturing the semiconductor device 1 includes a step (d) of preparing a second substrate 20 including a second support substrate 21 and a second insulating film 23 disposed on the second support substrate 21, the second insulating film including an organic insulating material, and a step (g1) of bonding the first insulating film 13 and the second insulating film 23 after step (d). In this case, for the reason described above, the first substrate 10 and the second substrate 20 are bonded in a state where the surface roughness of the first substrate 10 is reduced. Therefore, according to the method for manufacturing the semiconductor device 1, the bonding strength between the first substrate 10 and the second substrate 20 can be improved.

In the method for manufacturing the semiconductor device 1, the tensile modulus is 3.0 GPa or less. In this case, the wear of the grinding apparatus 100 used for the fly-cutting method is further suppressed. That is, in the configuration in which the tensile modulus of the organic insulating material included in the first insulating film 13 is 3.5 GPa or less, the wear of the diamond cutting tool of the grinding apparatus 100 is further suppressed. Therefore, according to the method for manufacturing the semiconductor device 1, the surface roughness of the first substrate 10 can be further reduced.

In the method for manufacturing the semiconductor device 1, the organic insulating material included in the first insulating film 13 is polyimide. According to the method for manufacturing the semiconductor device 1, the first insulating film 13 in which the tensile modulus of the organic insulating material is 3.5 GPa or less can be easily realized.

### Second Embodiment

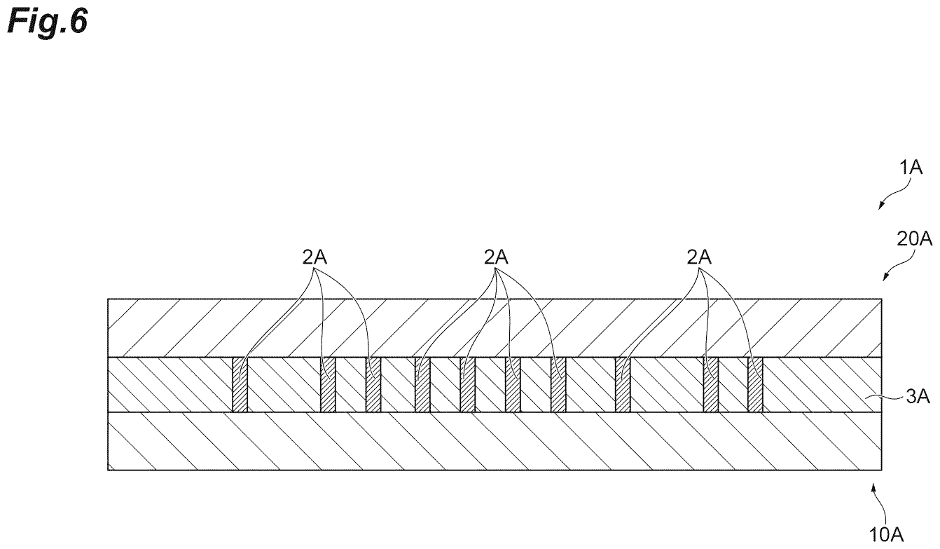

Next, with reference to FIGS. 6 to 10, a semiconductor device and a method for manufacturing the semiconductor device according to a second embodiment of the present disclosure will be described. In the following description, points different from the first embodiment will be mainly described, and descriptions similar to or overlapping with the first embodiment may be omitted.

### (Configuration of Semiconductor Device)

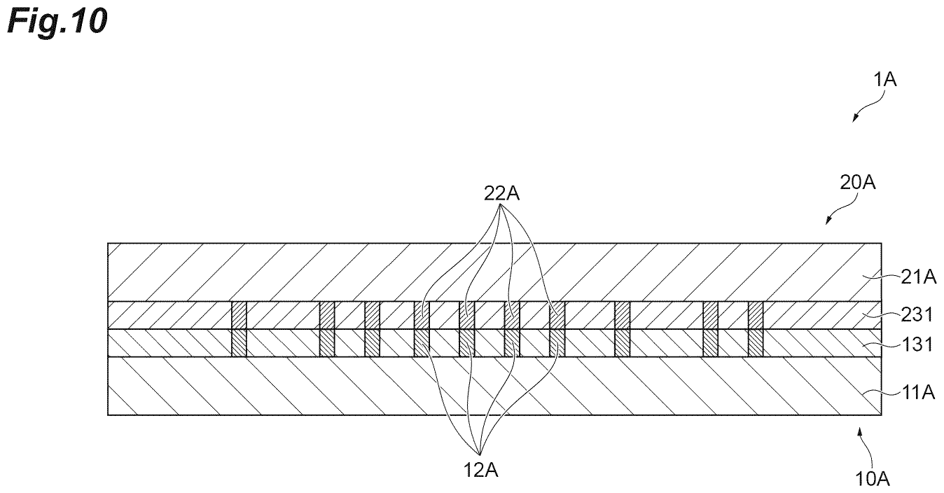

First, with reference to FIG. 6, the configuration of a semiconductor device 1A according to the second embodiment will be described. FIG. 6 shows an example of the semiconductor device according to the second embodiment of the present disclosure. As shown in FIG. 6, the semiconductor device 1A is, for example, an example of a semiconductor package, and includes a plurality of electrodes 2A, an insulating film 3A, a first substrate 10A, and a second substrate 20A. The electrode 2A is formed by bonding a first conductive part 12A of a first substrate 10A and a second conductive part 22A of a second substrate 20A, which will be described later (see FIG. 10). The insulating film 3A is formed by bonding a first insulating film 13A (first portion 131) of the first substrate 10A and a second insulating film 23A (first portion 231) of the second substrate 20A, which will be described later (see FIG. 10). Here, the tensile modulus of the organic insulating material included in the first insulating film 13A, which becomes the insulating film 3A, is 3.5 GPa or less, and may be 3.0

GPa or less, and may be 2.8 GPa or less. Furthermore, in the configuration in which the second insulating film 23A also includes an organic insulating material, the tensile modulus of the organic insulating material may be 3.5 GPa or less, may be 3.0 GPa or less, and may be 2.8 GPa or less. The organic insulating material includes, for example, polyimide, a polyimide precursor, polyamide-imide, benzocyclobutene (BCB), polybenzoxazole (PBO), or a PBO precursor.

In the semiconductor device 1A, the first substrate 10A and the second substrate 20A are bonded. The first substrate 10A may include a semiconductor element. The second substrate 20A may also include a semiconductor element. These semiconductor elements may be electrically connected to each other via the plurality of electrodes 2A. Since a configuration of the semiconductor elements included in the first substrate 10A and the second substrate 20A is the same as the configuration of the semiconductor elements included in the first substrate 10 and the second substrate 20, a detailed description is omitted.

### (Method for Manufacturing Semiconductor Device)

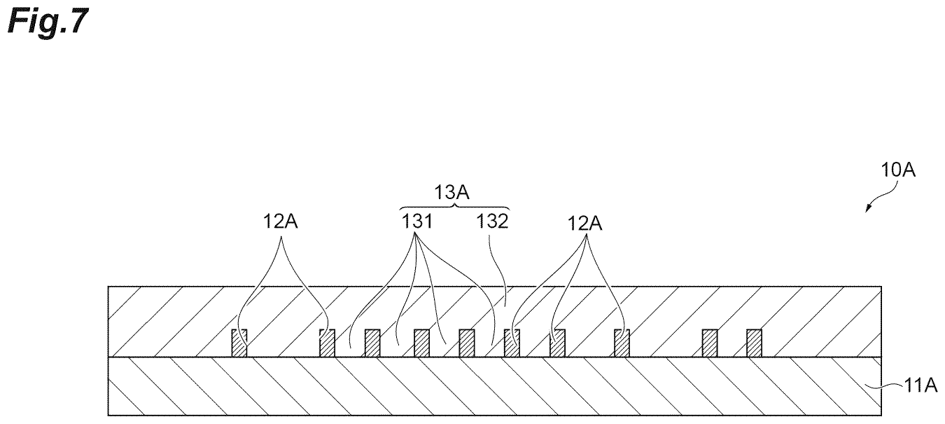

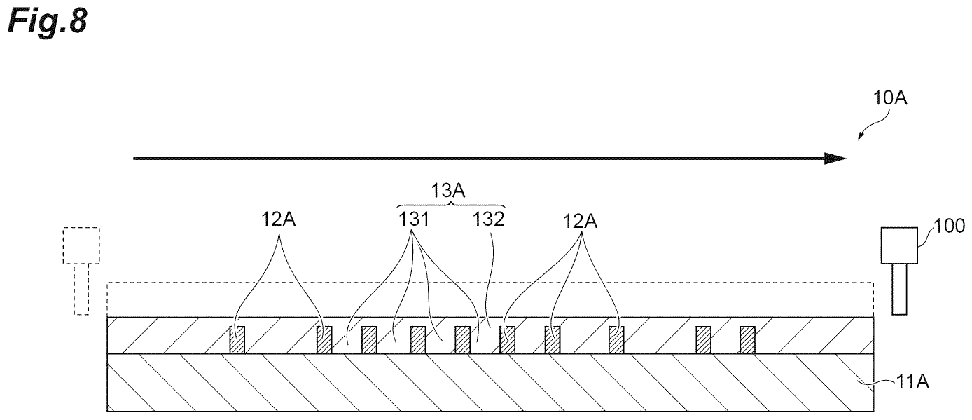

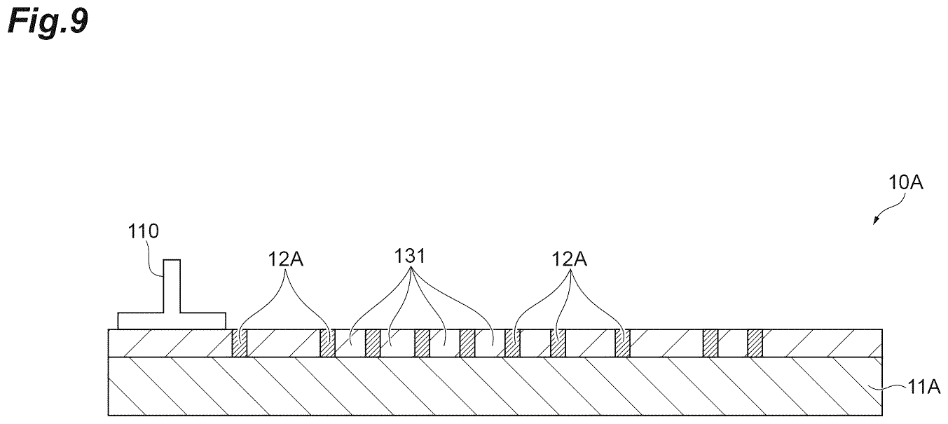

Next, with reference to FIGS. 7 to 10, a method for manufacturing the semiconductor device 1A will be described. FIG. 7 is a cross-sectional view for explaining the method for manufacturing the semiconductor device shown in FIG. 6, showing an example of a step of preparing a first substrate. FIG. 8 is a cross-sectional view for explaining the method for manufacturing the semiconductor device shown in FIG. 6, showing an example of a step of cutting a second portion of a first insulating film by a fly-cutting method. FIG. 9 is a cross-sectional view for explaining the method for manufacturing the semiconductor device shown in FIG. 6, showing an example of a step of polishing a surface of the cut first insulating film. FIG. 10 is a cross-sectional view for explaining the method for manufacturing the semiconductor device shown in FIG. 6, showing an example of a step of bonding a first conductive part and a second conductive part.

The semiconductor device 1A can be manufactured, for example, through the following steps (h) to (n). That is, the method for manufacturing the semiconductor device 1 includes the following steps (h) to (n).

h) A step of preparing a substrate including a first support substrate, and a first conductive part and a first insulating film disposed on the first support substrate.

i) A step of cutting at least a part of the first insulating film by a fly-cutting method without cutting the first conductive part.

j) A step of polishing a surface of the first insulating film, which is performed after step (i).

k) A step of preparing a substrate including a second support substrate, and a second conductive part and a second insulating film disposed on the second support substrate.

l) A step of cutting at least a part of the second insulating film by a fly-cutting method without cutting the second conductive part.

m) A step of polishing a surface of the second insulating film, which is performed after step (l).

n) A step of bonding the first substrate and the second substrate, which is performed after steps (j) and (m).

Further, the step n) of bonding the first substrate and the second substrate includes the following steps.

n1) A step of bonding the first insulating film of the first substrate and the second insulating film of the second substrate.

n2) A step of bonding the first conductive part of the first substrate and the second conductive part of the second substrate.

[Step (h)]

Step (h) is a step of preparing the first substrate 10A. To prepare the first substrate 10A, first, a first support substrate 11A including a first conductive part 12A and a first insulating film 13A is prepared. Since a configuration of the first support substrate 11A is the same as the configuration of the first support substrate 11, a detailed description is omitted.

In the first substrate 10A prepared in step (h), the first conductive part 12A is disposed on the first support substrate 11A. Such a first conductive part 12A is disposed on the first support substrate 11A, for example, using a photosensitive material. In this case, the first conductive part 12A is disposed on the first support substrate 11A, for example, as follows. First, an underlying layer is disposed on the first support substrate 11A. This underlying layer is a portion that serves as a seed during electrolytic plating, which will be described later. Next, a resist layer is disposed on the underlying layer. In one example, a film-like insulating material is attached as the resist layer onto the first support substrate 11A by a lamination process.

This lamination process is performed, for example, with the temperature set to 40° C. or more and 120° C. or less. For this reason, it is preferable to use a photosensitive insulating film that can be laminated at 40° C. or more and 120° C. or less as the film-like insulating material. By setting the laminatable temperature to 40° C. or more, it is possible to suppress an increase in the tack (adhesiveness) of the photosensitive insulating film at room temperature and maintain good handleability of the photosensitive insulating film. By setting the laminatable temperature of the photosensitive insulating film to 120° C. or less, it is possible to suppress the occurrence of warpage in the photosensitive insulating film after the lamination process. Note that “room temperature” indicates about 25° C.

Next, an opening is provided in the resist layer by performing exposure and development on the resist layer. In the present embodiment, a plurality of openings are provided in the resist layer corresponding to the plurality of electrodes 2A. Specifically, a pattern corresponding to the first conductive part 12A is formed by performing predetermined exposure with a photomask placed on the resist layer. Then, the exposed resist layer is developed using a developer. As a result, the unexposed portions of the resist layer are dissolved, and a plurality of openings are formed. At this time, the underlying layer is exposed within the plurality of openings.

Next, the first conductive part 12A is disposed so that at least a part thereof is located within the plurality of openings. In one example, the first conductive part 12A is formed by electrolytic plating using the underlying layer exposed in the plurality of openings as a seed layer. The first conductive part 12A is formed so that at least a part thereof is located within the plurality of openings. In this case, for example, the plurality of openings are filled by copper plating, and the first conductive part 12A is formed.

Next, the resist layer is stripped from the first support substrate 11A. The stripping is performed using a commonly used stripping solution.

The first conductive part 12A provided by the above method consists of, for example, a copper pillar including a diameter of 0.5 μm or more and 20 μm or less. Further, the volume resistivity of the first conductive part 12A is, for example, 40 μΩ·cm or less from the viewpoint of transmission efficiency. From the viewpoint of suppressing the amount of heat generation, the volume resistivity is preferably 30 μΩ·cm or less. Further, from the viewpoint of reliability, the volume resistivity is more preferably 20 μΩ·cm or less. Note that the volume resistivity is usually 3 μΩ·cm or more.

In the first substrate 10A prepared in step (h), the first insulating film 13A is disposed on the first support substrate 11A. More specifically, the first insulating film 13A is disposed on the first support substrate 11A and on the first conductive part 12A. The first insulating film 13A also includes an organic insulating material. The tensile modulus of the organic insulating material is 3.5 GPa or less, and may be 3.0 GPa or less, and may be 2.8 GPa or less. Such a first insulating film 13A is provided, for example, by applying a liquid organic insulating material onto the surface of the first support substrate 11A and the surface of the first conductive part 12A by spin coating.

The organic insulating material includes, for example, polyimide, a polyimide precursor, polyamide-imide, benzocyclobutene (BCB), polybenzoxazole (PBO), or a PBO precursor.

Furthermore, in the first substrate 10A prepared in step (h), the first insulating film 13A has a first portion 131 and a second portion 132. The first portion 131 covers a surface of the first support substrate 11A and a side surface of the first conductive part 12A. The second portion 132 is located on the first portion 131 and covers a top surface of the first conductive part 12A. A thickness of the second portion 132 is, for example, 0.5 μm or more and 5 μm or less. The first portion 131 and the second portion 132 are provided integrally.

A thickness of the first insulating film 13A formed on the first support substrate 11A is, for example, 10 μm or less, preferably 5 μm or less, and more preferably 3 μm or less. Further, the thickness of the first insulating film 13A may be 1 μm or more. The thickness of the first insulating film 13A is, for example, a total thickness of the first portion 131 and the second portion 132. Note that the first insulating film 13A may be formed from an inorganic material.

After providing the first insulating film 13A, the first insulating film 13A may be heat-cured. Since the heating conditions in this case are the same as the heating conditions for heat-curing the first insulating film 13, a detailed description is omitted.

Through the above step (h), as shown in FIG. 7, a substrate including the first support substrate 11A, and the first conductive part 12A and the first insulating film 13A disposed on the first support substrate 11A is prepared. Therefore, it can also be said that step (h) includes a step of disposing the underlying layer on the first support substrate 11A, a step of disposing the resist layer on the underlying layer, a step of providing the opening in the resist layer by performing exposure and development on the resist layer, a step of disposing the first conductive part 12A so that at least the part thereof is located within the opening, and a step of disposing the first insulating film 13A on the first support substrate 11A and on the first conductive part 12A.

[Step (i)]

Step (i) is a step of cutting the first insulating film 13A. In step (i), the first insulating film 13A is cut by a fly-cutting method. In one example, at least a part of the first insulating film 13A is cut by the fly-cutting method without cutting the first conductive part 12A.

In step (i) in the present embodiment, while leaving the first portion 131 of the first insulating film 13A that covers the surface of the first support substrate 11A and the side surface of the first conductive part 12A, the second portion 132 that covers the top surface of the first conductive part 12A is cut by the fly-cutting method. More specifically, as shown in FIG. 8, the second portion 132 is cut by the fly-cutting method so that the surface of the second portion 132 protrudes from the top surface of the first conductive part 12A (so that a part of the second portion 132 remains). That is, in step (i) in the present embodiment, the thickness of the second portion 132 is reduced by the fly-cutting method. Therefore, in step (i) in the present embodiment, it can also be said that a part of the second portion 132 is removed by cutting. A thickness of the second portion 132 to be cut by the fly-cutting method is, for example, 0.5 μm or more and 20 μm or less. Therefore, at the time when step (i) in the present embodiment is completed, the thickness of the second portion 132 is, for example, 3.0 μm or more and 10 μm or less.

In the fly-cutting method, similarly to the first embodiment, for example, the grinding apparatus 100 using the diamond cutting tool is used. In this case as well, as shown in FIG. 8, the second portion 132 is cut by moving the grinding apparatus 100 in the predetermined direction on the first substrate 10A. Note that the cutting of the second portion 132 by the fly-cutting method can also be referred to as a planarization process. Further, in step (i) as well, etching or the like may be combined in addition to the fly-cutting method.

At the time when step (i) in the present embodiment is completed, the surface roughness of the second portion 132 cut by the fly-cutting method is, for example, 10 nm or more and 100 nm or less. In the present embodiment, the surface roughness is the arithmetic mean roughness (Ra) defined in JIS B 0601 2001. The surface roughness of the second portion 132 after cutting is measured, for example, by scanning a range of 100 μm×100 μm including the second portion 132 using the laser microscope (“LEXT OLS3000” manufactured by Olympus Corporation).

[Step (j)]

Step (j) is a step of polishing the surface of the first insulating film 13A, and is a step performed after the grinding of step (i). In step (j) in the present embodiment, as shown in FIG. 9, the remaining portion of the cut second portion 132 is polished so that the surface of the first portion 131 and the top surface of the first conductive part 12A are flush. More specifically, by polishing the surface of the remaining portion of the cut second portion 132, the second portion 132 remaining after step (i) is removed, and the surface of the first portion 131 and the top surface of the first conductive part 12A are made flush. This exposes the top surface of the first conductive part 12A. In step (j) in the present embodiment, after making the surface of the first portion 131 and the top surface of the first conductive part 12A flush, the surface of the first portion 131 and the top surface of the first conductive part 12A are further polished.

For the polishing in step (j) as well, a method such as the grinder for processing electronic materials or the CMP (Chemical Mechanical Polishing) method can be used. In step (j) in the present embodiment, the surface of the second portion 13b is polished by the CMP method. That is, in step (j) in the present embodiment, it can be said that the surface of the cut first insulating film 13A is polished by the CMP method. In the CMP method, for example, the polishing apparatus 110 is used. In this case, as shown in FIG. 9, by rotating the polishing apparatus 110 while pressing it against the surface of the second portion 132, the surface of the second portion 132 is polished by mechanical friction between the polishing liquid applied to the surface of the polishing apparatus 110 and the second portion 132. Note that the polishing of the surface of the second portion 132 by the CMP method can also be referred to as a planarization process.

At the time when step (j) in the present embodiment is completed, by the above-mentioned polishing, a surface roughness of the first portion 131 is, for example, 0.5 nm or more and 3.0 nm or less. Further, the surface roughness of the top surface of the first conductive part 12A is, for example, 0.5 nm or more and 3.0 nm or less. The surface roughness is the arithmetic mean roughness (Ra) defined in JIS B 0601 2001. The surface roughness of the first portion 131 and the surface roughness of the top surface of the first conductive part 12A after polishing are measured, for example, by a method similar to that for the surface roughness of the second portion 132 after cutting.

[Step (k)]

Step (k) is a step of preparing a second substrate 20A different from the first substrate 10A. In step (k), a second substrate 20A including a second support substrate 21A, and a second conductive part 22A and a second insulating film 23A disposed on the second support substrate 21A is prepared. More specifically, it includes a second support substrate 21A, a second conductive part 22A disposed on the second support substrate 21A, and a second insulating film 23 disposed on the second support substrate 21A and the second conductive part 22A.

In the second substrate 20A prepared in step (k), the second insulating film 23A has a first portion 231 that covers a surface of the second support substrate 21A and a side surface of the second conductive part 22A, and a second portion that is located on the first portion 231 and covers a top surface of the second conductive part 22A. Here, the second insulating film 23A may include an organic insulating material or may include an inorganic insulating material. In a configuration in which the second insulating film 23A includes an organic insulating material, the tensile modulus of the organic insulating material may be 3.5 GPa or less, may be 3.0 GPa or less, and may be 2.8 GPa or less. Since the method for preparing the second substrate 20A is the same as the method for preparing the first substrate 10A, a detailed description is omitted, but the second substrate 20A is prepared through the steps described above. The second substrate 20A does not need to have a completely identical configuration to the first substrate 10A, and a thickness or forming material of the second support substrate 21A, and a thickness or forming material of the second insulating film 23A, and the like may be different from those of the first substrate 10A.

[Step (l)]

Step (1) is a step of cutting the second insulating film 23A. Since the method for cutting the second insulating film 23A is the same as the method for cutting the first insulating film 13A, a detailed description is omitted, but the second insulating film 23A is cut through the step shown in FIG. 8. In step (l), the second portion of the second insulating film 23A may be cut so that the surface of the second portion of the second insulating film 23A protrudes from the top surface of the second conductive part 22A.

[Step (m)]

Step (m) is a step of polishing the surface of the second insulating film 23A, and is a step performed after step (1). Since the method for polishing the surface of the second insulating film 23A is the same as the method for polishing the surface of the first insulating film 13A, a detailed description is omitted, but the surface of the second insulating film 23A is cut through the step shown in FIG. 9. In step (m), the surface of the second portion of the second insulating film 23A may be polished so that the surface of the first portion 231 and the top surface of the second conductive part 22A are flush. This exposes the top surface of the second conductive part 22A.

[Step (n)]

Step (n) is a step of bonding the first substrate 10A and the second substrate 20A, and is a step performed after steps (j) and (m). In step (n), first, the first insulating film 13A of the first substrate 10A and the second insulating film 23A of the second substrate 20A are bonded. Here, alignment of at least one of the first substrate 10A and the second substrate 20A is performed so that the first conductive part 12A of the first substrate 10A and the second conductive part 22A of the second substrate 20A oppose each other. Alignment of both the first substrate 10A and the second substrate 20A may be performed. For such alignment, an alignment mark or the like may be provided on at least one of the first substrate 10A and the second substrate 20A.

When bonding the first substrate 10A and the second substrate 20A, after removing organic matter or metal oxides adhering to the surfaces of the first substrate 10A and the second substrate 20A, alignment of the second substrate 20A with respect to the first substrate 10A is performed. Then, when the alignment is completed, the first portion 131 of the first insulating film 13A and the first portion 231 of the second insulating film 23A are bonded by hybrid bonding. At this time, the first portion 131 and the first portion 231 may be uniformly heated and then bonded. By bonding the first portion 131 and the first portion 231, the insulating film 3A of the semiconductor device 1A is formed as shown in FIG. 6.

A temperature difference between the first substrate 10A and the second substrate 20A during bonding is preferably 10° C. or less, for example. By such heat bonding at a uniform temperature, the first insulating film 13A is mechanically and firmly attached to the second insulating film 23A. Further, since it is heat bonding at a uniform temperature, positional deviation or the like at the bonding location is unlikely to occur, and high-precision bonding can be performed. Note that the bonding of the first substrate 10A and the second substrate 20A may be performed by other bonding methods, for example, they may be bonded by room temperature bonding or the like.

Next, when the bonding of the first insulating film 13A of the first substrate 10A and the second insulating film 23A of the second substrate 20A is completed, the first conductive part 12A of the first substrate 10A and the second conductive part 22A of the second substrate 20 are bonded. In the present embodiment, as shown in FIG. 10, when the bonding of the first insulating film 13A and the second insulating film 23A is completed, a predetermined heat or pressure or both are applied to bond the first conductive part 12A and the second conductive part 22A by hybrid bonding. In a configuration in which the first conductive part 12A and the second conductive part 22A are formed from copper, the annealing temperature here is preferably 150° C. or more and 400° C. or less, and more preferably 200° C. or more and 300° C. or less. By such a bonding process, an electrode 2A in which the first conductive part 12A and the second conductive part 22A are bonded is formed, and an electrode 2A in which the first conductive part 12A and the second conductive part 22A are mechanically and electrically and firmly bonded is formed. Note that the electrode bonding may be performed after the bonding of the first insulating film 13A and the second insulating film 23A, or may be performed simultaneously with the bonding of the first insulating film 13A and the second insulating film 23A.

Through the above steps, the semiconductor device 1A shown in FIG. 6 is manufactured.

In the method for manufacturing the semiconductor device 1A, the first substrate 10A includes the first conductive part 12A and the first insulating film 13A disposed on the first support substrate 11A. The tensile modulus of the organic insulating material included in the first insulating film 13A is 3.5 GPa or less. In step (i), at least a part of the first insulating film 13A is cut by the fly-cutting method without cutting the first conductive part 12A. According to the method for manufacturing the semiconductor device 1A, even in the configuration in which the first substrate 10A includes the first conductive part 12A, the surface roughness of the substrate can be reduced for the reason described above.

In the method for manufacturing the semiconductor device 1A, after cutting at least a part of the first insulating film 13A by the fly-cutting method in step (i), the surface of the first insulating film 13 is polished in step (j). In this case, a part of step (j) can be replaced by step (i). This makes it possible to reduce the surface roughness while shortening the processing time in step (j). Therefore, according to the method for manufacturing the semiconductor device 1A, the surface roughness can be easily reduced.

In the method for manufacturing the semiconductor device 1A, the surface of the cut first insulating film 13A is polished by the CMP method. According to the method for manufacturing the semiconductor device 1A, step (j) can be performed easily. In addition, the surface roughness of the first insulating film 13A can be reliably reduced.

The method for manufacturing the semiconductor device 1A comprises step (k) of preparing the second substrate 20A including the second support substrate 21A, the second insulating film 23A including an organic insulating material disposed on the second support substrate 21A, and the second conductive part 22A disposed on the second support substrate 21A, and step (n) of bonding the first conductive part 12A and the second conductive part 22A after steps (j) and (m). In this case, for the reason described above, the first substrate 10A and the second substrate 20A are bonded in a state where the surface roughness of the first substrate 10A is reduced. Therefore, according to the method for manufacturing the semiconductor device 1A, the bonding strength between the first substrate 10A and the second substrate 20A can be improved.

### EXAMPLES

Hereinafter, the present invention will be described more specifically with reference to Examples, but the present invention is not limited to these Examples.

### Example 1

Two substrates, each including a support substrate and a polyimide film including polyimide disposed on the support substrate, were prepared as corresponding to the first substrate 10 in the above-described embodiment. In each prepared substrate, the tensile modulus of the polyimide included in the polyimide film was 2.6 GPa.

Next, for each substrate, at least a part of the polyimide film was cut by the fly-cutting method so that the surface of the support substrate was not exposed. Next, for each substrate, the surface of the remaining portion of the cut polyimide film was polished by the CMP method so that the surface of the support substrate was not exposed.

Next, using the laser microscope (“LEXT OLS3000” manufactured by Olympus Corporation), a range of 100 μm×100 μm on each substrate surface was scanned to measure the surface roughness (arithmetic mean roughness (Ra) defined in JIS B 0601 2001) of the two substrates. Note that the surface roughness of the substrate here includes the surface roughness of the polyimide film. Next, the two substrates were bonded. Thereafter, the shear strength (bonding strength) of the two bonded substrates was measured. As a result, in Example 1, the surface roughness of the two substrates was 0.8 nm each, and the shear strength was 30.0 MPa.

### Example 2

In Example 2, two substrates similar to the substrate in Example 1 were prepared, except that the tensile modulus of the polyimide included in the polyimide film was 3.5 GPa. Next, for each substrate, at least a part of the polyimide film was cut by the fly-cutting method so that the surface of the support substrate was not exposed. Next, for each substrate, the surface of the remaining portion of the cut polyimide film was polished by the CMP method so that the surface of the support substrate was not exposed.

Thereafter, the surface roughness of the two substrates was measured in the same manner as in Example 1. Next, the two substrates were bonded. Thereafter, the shear strength of the two bonded substrates was measured. As a result, in Example 2, the surface roughness of the two substrates was 0.7 nm each, and the shear strength was 22.1 MPa.

### Example 3

In Example 3, two substrates similar to the substrate in Example 1 were prepared. Next, for each substrate, at least a part of the polyimide film was cut by the fly-cutting method so that the surface of the support substrate was not exposed. In Example 3, polishing of the surface of the polyimide film by the CMP method was not performed. That is, in Example 3, only cutting of the polyimide film by the fly-cutting method was performed.

Thereafter, the surface roughness of the two substrates was measured in the same manner as in Example 1. Next, the two substrates were bonded. Thereafter, the shear strength of the two bonded substrates was measured. As a result, in Example 3, the surface roughness of the two substrates was 15.89 nm each, and the shear strength was 19.4 MPa.

### Example 4

In Example 4, two substrates similar to the substrate in Example 2 were prepared. Next, for each substrate, at least a part of the polyimide film was cut by the fly-cutting method so that the surface of the support substrate was not exposed. In Example 4, polishing of the surface of the polyimide film by the CMP method was not performed. That is, in Example 4, only cutting of the polyimide film by the fly-cutting method was performed.

Thereafter, the surface roughness of the two substrates was measured in the same manner as in Example 1. Next, the two substrates were bonded. Thereafter, the shear strength of the two bonded substrates was measured. As a result, in Example 4, the surface roughness of the two substrates was 35.4 nm each, and the shear strength was 8.2 MPa.

### Comparative Example 1

In Comparative Example 1, two substrates similar to the substrate in Example 1 were prepared. Next, the surface of the polyimide film was polished by a CMP method so that the surface of the support substrate was not exposed. In Comparative Example 1, cutting of the polyimide film by the fly-cutting method was not performed. That is, in Comparative Example 1, only polishing of the surface of the polyimide film by the CMP method was performed.

Thereafter, the surface roughness of the two substrates was measured in the same manner as in Example 1. Next, the two substrates were bonded. Thereafter, the shear strength of the two bonded substrates was measured. As a result, in Comparative Example 1, the surface roughness of the two substrates was 0.8 nm each, and the shear strength was 27.1 MPa.

### Comparative Example 2

In Comparative Example 2, two substrates similar to the substrate in Example 2 were prepared. Next, the surface of the polyimide film was polished by a CMP method so that the surface of the support substrate was not exposed. In Comparative Example 2, cutting of the polyimide film by the fly-cutting method was not performed. That is, in Comparative Example 2, only polishing of the surface of the polyimide film by the CMP method was performed.

Thereafter, the surface roughness of the two substrates was measured in the same manner as in Example 1. Next, the two substrates were bonded. Thereafter, the shear strength of the two bonded substrates was measured. As a result, in Comparative Example 2, the surface roughness of the two substrates was 0.5 nm each, and the shear strength was 28.0 MPa.

When performing general hybrid bonding, it is desired that the surface roughness of the substrate be 50 nm or less, and preferably 1 nm or less. Therefore, in evaluating the surface roughness of each substrate in Experimental Examples 1, 2, 3, 4 and Comparative Examples 1, 2, a case where the surface roughness of the substrate was 1 nm or less was evaluated as “Good (A)”, a case where the surface roughness of the substrate was 50 nm or less was evaluated as “Acceptable (B)”, and a case where the surface roughness of the substrate was greater than 50 nm was evaluated as “Fail (F)”.

In Example 1, since the surface roughness of the two substrates was 0.8 nm each, Example 1 was evaluated as “A” for substrate surface roughness. In Example 2, since the surface roughness of the two substrates was 0.7 nm each, Example 2 was evaluated as “A” for substrate surface roughness. In Example 3, since the surface roughness of the two substrates was 15.89 nm each, Example 3 was evaluated as “B” for substrate surface roughness. In Example 4, since the surface roughness of the two substrates was 35.4 nm each, Example 4 was evaluated as “B” for substrate surface roughness. In Comparative Example 1, since the surface roughness of the two substrates was 0.8 nm each, Comparative Example 1 was evaluated as “A” for substrate surface roughness. In Comparative Example 2, since the surface roughness of the two substrates was 0.5 nm each, Comparative Example 2 was evaluated as “A” for substrate surface roughness.

Further, after performing general hybrid bonding, it is desired that the shear strength between the bonded substrates be 5 MPa or more, and preferably 20 MPa or more. Therefore, in evaluating the shear strength after bonding with another substrate in Experimental Examples 1, 2, 3, 4 and Comparative Examples 1, 2, a case where the shear strength was 20 MPa or more was evaluated as “Good (A)”, a case where the shear strength was 5 MPa or more was evaluated as “Acceptable (B)”, and a case where the shear strength was less than 5 MPa was evaluated as “Fail (F)”.

In Example 1, since the shear strength was 30.0 MPa, Example 1 was evaluated as “A” for shear strength. In Example 2, since the shear strength was 22.1 MPa, Example 2 was evaluated as “A” for shear strength. In Example 3, since the shear strength was 19.4 MPa, Example 3 was evaluated as “B” for shear strength. In Example 4, since the shear strength was 8.2 MPa, Example 4 was evaluated as “B” for shear strength. In Comparative Example 1, since the shear strength was 27.1 MPa, Comparative Example 1 was evaluated as “A” for shear strength. In Comparative Example 2, since the shear strength was 28.0 MPa, Comparative Example 2 was evaluated as “A” for shear strength.

Table 1 below summarizes the results of Examples 1, 2, 3, 4 and Comparative Examples 1, 2.

TABLE 1

| | | | | | Compar- | Compar- |
|---|---|---|---|---|---|---|
| | Exam- | Exam- | Exam- | Exam- | ative | ative |
| | ple 1 | ple 2 | ple 3 | ple 4 | Example 1 | Example 2 |
| surface | A | A | B | B | A | A |
| roughness | | | | | | |
| shear | A | A | B | B | A | A |
| strength | | | | | | |

First, focusing on the surface roughness. As shown in Table 1, there were no Examples or Comparative Examples evaluated as “F” for substrate surface roughness. Therefore, it can be understood that when the tensile modulus of the polyimide (organic insulating material) included in the polyimide film (insulating film) is 3.5 GPa or less, the surface roughness of the substrate can be reduced even with a method using the fly-cutting method.

Furthermore, Examples 1 and 2, in which the surface of the polyimide film was polished by the CMP method after cutting the polyimide film by the fly-cutting method, and Comparative Examples 1 and 2, in which only polishing of the surface of the polyimide film by the CMP method was performed, were judged as “A” for surface roughness. On the other hand, Examples 3 and 4, in which polishing of the surface of the polyimide film by the CMP method was not performed, were judged as “B” for surface roughness. Therefore, it can be understood that when the tensile modulus of the polyimide (organic insulating material) included in the polyimide film (insulating film) is 3.5 GPa or less, and the surface of the polyimide film (insulating film) is polished by the CMP method after cutting the polyimide film (insulating film) by the fly-cutting method, the surface roughness of the substrate can be further reduced.

Next, focusing on the shear strength. Here, the smaller the surface roughness of the substrate, the higher the bonding strength between substrates bonded by hybrid bonding. Therefore, similar to the surface roughness, there were no Examples or Comparative Examples evaluated as “F” for shear strength. From the above, it can be understood that when the tensile modulus of the polyimide (organic insulating material) included in the polyimide film (insulating film) is 3.5 GPa or less, the shear strength between bonded substrates can be improved.

Furthermore, in Examples 1 and 2 and Comparative Examples 1 and 2, which were judged as “A” for surface roughness, the shear strength was also judged as “A”. On the other hand, in Examples 3 and 4, which were judged as “B” for surface roughness, the shear strength was also judged as “B”. Therefore, it can be understood that when the tensile modulus of the polyimide (organic insulating material) included in the polyimide film (insulating film) is 3.5 GPa or less, and the surface of the polyimide film (insulating film) is polished by the CMP method after cutting the polyimide film (insulating film) by the fly-cutting method, the shear strength between bonded substrates can be further improved.

When comparing the fly-cutting method and the CMP method, the thickness of the polyimide film (insulating film) removed per unit time by the fly-cutting method tends to be greater than the same thickness removed by the CMP method. Therefore, when removing the same thickness of the polyimide film, the time required for the fly-cutting method is expected to be shorter than the time required for the CMP method. That is, it is expected that the processing time in Examples 1 and 2, in which polishing of the polyimide film by the CMP method was performed after cutting the polyimide film by the fly-cutting method, is shorter than the processing time in Comparative Examples 1 and 2, in which only polishing of the polyimide film by the CMP method was performed. Therefore, it is understood that by replacing a part of the step of polishing the polyimide film by the CMP method with the step of cutting the polyimide film by the fly-cutting method, the processing time in the step of polishing can be shortened.

Although the embodiments of the present disclosure have been described above, the present invention is not limited to the above-described embodiments, and appropriate modifications may be made without departing from the spirit of the invention.

In the second embodiment described above, the first conductive part 12A and the second conductive part 22A are formed by electrolytic plating, but the invention is not limited to this. For example, the first conductive part 12A and the second conductive part 22A may be formed using at least one of sputtering and electroless plating. Alternatively, the first conductive part 12A and the second conductive part 22A may be formed by combining at least one of sputtering, electroplating, and electroless plating with a step of applying a copper paste and a sintering step.

In the second embodiment described above, in step (i), while leaving the first portion 131 of the first insulating film 13A that covers the surface of the first support substrate 11A and the side surface of the first conductive part 12A, the second portion 132 that covers the top surface of the first conductive part 12A was cut by the fly-cutting method, but step (i) is not limited to this. For example, in step (i), the second portion 132 may be cut by the fly-cutting method so that the surface of the first portion 131 and the top surface of the first conductive part 12A are flush. That is, in step (i), the entire second portion 13b may be removed by cutting by the fly-cutting method. In this case, in step (j), the surface of the first portion 131 may be polished. Further, in step (j), in addition to the surface of the first portion 131, the top surface of the first conductive part 12A may be polished.

When the second portion 132 is cut in step (i) so that the surface of the first portion 131 and the top surface of the first conductive part 12A are flush, it becomes possible to reduce the surface roughness while further shortening the working time in step (j). Therefore, in this case, the surface roughness can be reduced even more easily.

### REFERENCE SIGNS LIST

1, 1A . . . Semiconductor device, 10, 10A . . . first substrate, 11, 11A . . . first support substrate, 12A . . . first conductive part, 13, 13A . . . first insulating film, 20, 20A . . . second substrate, 21, 21A . . . second support substrate, 22A . . . second conductive part, 23, 23A . . . second insulating film.

1. A method for manufacturing a semiconductor device comprising:
preparing a first substrate,
wherein the first substrate includes:
a first support substrate, and
a first insulating film disposed on the first support substrate, and
wherein the first insulating film includes an organic insulating material; and
cutting at least a part of the first insulating film by a fly-cutting method,
wherein a tensile modulus of the organic insulating material is 3.5 GPa or less.

2. The method for manufacturing a semiconductor device according to claim 1, further comprising polishing a surface of the first insulating film,
wherein the polishing is performed after the cutting.

3. The method for manufacturing a semiconductor device according to claim 2, wherein in the polishing, the surface of the cut first insulating film is polished by a CMP method.

4. The method for manufacturing a semiconductor device according to claim 1,
wherein, the first substrate further includes a first conductive part disposed on the first support substrate, and
wherein, in the cutting, at least a part of the first insulating film is cut by the fly-cutting method without cutting the first conductive part.

5. The method for manufacturing a semiconductor device according to claim 1, further comprising:
preparing a second substrate,
wherein the second substrate includes:
a second support substrate;
a second insulating film disposed on the second support substrate; and
bonding the first insulating film and the second insulating film.

6. The method for manufacturing a semiconductor device according to claim 5,
wherein, the first substrate further includes a first conductive part disposed on the first support substrate,
wherein, the second substrate further includes a second conductive part disposed on the second support substrate, and
wherein, in the bonding, the first conductive part and the second conductive part are further bonded.

7. The method for manufacturing a semiconductor device according to claim 1, wherein the tensile modulus of the organic insulating material is 3.0 GPa or less.

8. The method for manufacturing a semiconductor device according to claim 1, wherein the organic insulating material includes polyimide.

9. A semiconductor device comprising:
a first substrate including a first support substrate and a first insulating film disposed on the first support substrate, the first insulating film including an organic insulating material; and
a second substrate including a second support substrate and a second insulating film disposed on the second support substrate,
wherein, the first insulating film and the second insulating film are bonded, and
wherein, a tensile modulus of the organic insulating material is 3.5 GPa or less.

10. The semiconductor device according to claim 9,
wherein, the first substrate further includes a first conductive part disposed on the first support substrate,
wherein, the second substrate further includes a second conductive part disposed on the second support substrate, and
wherein, an electrode formed by bonding the first conductive part and the second conductive part is provided.

11. The semiconductor device according to claim 9, wherein the tensile modulus of the organic insulating material is 3.0 GPa or less.

12. The semiconductor device according to claim 9, wherein the organic insulating material includes polyimide.

13. The semiconductor device according to claim 9,
wherein, the second insulating film includes an organic insulating material, and
wherein, a tensile modulus of the organic insulating material in the second insulating film is 3.5 GPa or less.
